(19) United States
(12) Patent Application Publication
(10) Pub. No.: US 2014/0061447 A1
(43) Pub. Date: Mar. 6, 2014

(54) RADIATION SENSOR

(71) Applicants: STMicroelectronics Pte Ltd, Singapore (SG); STMicroelectronics (Research & Development) Limited, Marlow (GB)

(72) Inventors: Colin Campbell, Strathaven (GB); Laurent Herard, Grenoble (FR)

(73) Assignees: STMicroelectronics Pte Ltd, Singapore (SG); STMicroelectronics (Research & Development) Limited, Marlow (GB)

(21) Appl. No.: 14/017,768

(22) Filed: Sep. 4, 2013

(30) Foreign Application Priority Data
Sep. 6, 2012 (GB) 1215930.7

(51) Int. Cl. G01S 17/02; G01R 3/00

(52) U.S. Cl. CPC G01S 17/026; G01R 3/00
USPC 250/221; 29/592.1; 250/239

(57) ABSTRACT

A sensor package includes a radiation source and a radiation detector provided on a substrate. A cover member is mounted on or affixed to the substrate over the source and detector. The cover member includes an opaque housing, a first transparent portion provided over the source, a second transparent portion provided over the detector and a transparent insert within the housing and positioned at one of said transparent portions. An opaque protrusion is provided on the housing separating a region associate with the first transparent portion (and radiation source) from a region associated with the second transparent portion (and detector), the protrusion attached to a surface of the substrate.

### PRIORITY CLAIM

This application claims priority from Great Britain Application for Patent No. 1215930.7 filed Sep. 6, 2012, the disclosure of which is incorporated by reference.

### TECHNICAL FIELD

The present disclosure relates to a radiation sensor and in particular to a proximity sensor, and a method of manufacture of a proximity sensor.

### BACKGROUND

Proximity sensors typically comprise a radiation source and a corresponding detector, the detector comprising a relatively small number of exposed light sensitive pixels (from a single pixel up to, for example, a 10×10 pixel array). At its simplest the proximity sensor is capable of indicating the presence or absence of a user or object. Additional computation and illuminator complexity can provide enhanced data such as the range to an object.

Proximity sensing is achieved by: emitting light from the radiation source; capturing light which is reflected back to the detector by an object; and processing the reflected light to determine the proximity of the object to the sensor.

Proximity sensors are also used in many applications, including on mobile communications devices and vehicle parking sensors.

The source and the detector have historically been provided in separate packages with separate control circuitry. Recently, it has been suggested to incorporate a source and a detector as part of a single package. However, the emission of stray light from the source can cause readout errors and is a significant obstacle to creating a practically viable package.

### SUMMARY

According to a first aspect there is provided a sensor package comprising a radiation source and radiation detector provided on a substrate; and a cover member mounted on or affixed to the substrate over the source and detector; wherein the cover member comprises: an opaque housing; a first transparent portion provided over the source; a second transparent portion provided over the detector; and a transparent insert within the housing and at one or more of said transparent portions.

“Opaque” means opaque to the radiation emitted by the source. Similarly, “transparent” means transparent to the radiation emitted by the source.

The transparent insert is therefore a mechanically integrated part of the package, rather than a separate part that is fixed to the package.

The transparent insert may comprise a window. A “window” means an object, usually a plate, transparent to radiation emitted by source. Alternatively, the transparent insert may comprise an object or a surface shaped to provide an optical function. The optical function may be a focusing function or a collimation function, for example.

A transparent insert is “within” the housing if it is supported by the housing and held securely therein without any further affixing mechanism being required for any orientation of the housing. Examples include having side surfaces entirely bounded by the housing; or having a perimeter portion bounded at both upper and lower surface by the housing.

Optionally, the transparent insert spans the transparent portion.

Optionally, both first and second transparent portions comprise a transparent insert within the housing.

Optionally, one of said first and second transparent portions comprises a transparent insert within the housing and the other of said first and second transparent portions comprises an aperture in the housing.

Optionally, the first transparent portion comprises a transparent insert within the housing; and the second transparent portion comprises an aperture in the housing.

Optionally, the housing also comprises a protrusion formed between the first and second transparent portions.

Optionally, the protrusion provides a transverse barrier across a central portion of the width of the package or across the entire width of the package.

Optionally, the protrusion extends downwards and contacts the substrate or other underlying components.

Optionally, the first and/or second transparent portions are flush or recessed with respect to an upper surface of the housing.

Optionally, the housing is formed from optically opaque thermoplastic molding material. For example, LCP 6130 material may be used.

Optionally, the housing comprises an aperture which functions as an air vent for the packaged sensor.

Optionally, the source comprises a VCSEL.

Optionally, the detector comprises a single photon avalanche detector (SPAD).

Optionally, the package also comprises a reference array.

Optionally, the package also comprises an ambient light sensor.

According to a second aspect there is provided a cover member comprising: an opaque housing; a first transparent portion; a second transparent portion; and a transparent insert within the housing.

According to a third aspect there is provided a method of manufacturing a sensor package comprising: providing a radiation source and a radiation detector on a substrate; forming a cover member with an opaque housing, a first transparent portion to be provided over the source, a second transparent portion to be provided over the detector; forming a transparent insert within the housing at one or more of said transparent portions; and mounting or affixing the cover member on/to the substrate.

Optionally the step of mounting or affixing the cover member on/to the substrate comprises depositing a transparent glue (preferably over a VCSEL and reference array) and placing a portion of the package over the glue. The portion that is used as fiduciary point in this method is preferably a protrusion that is formed between the first and second transparent portions.

According to a fourth aspect there is provided a method of forming a cover member comprising forming an opaque housing with a first transparent portion to be provided over the source and a second transparent portion to be provided over the detector; and forming a transparent insert within the housing at one or more of said transparent portions.

Optionally, the method comprises a twin-shot injection overmolding process; wherein the transparent insert is formed and then the cover member is overmolded onto the window.

Optionally, the transparent insert is formed by molding round a tree sprue and the housing is overmolded around the tree sprue to create an internally enclosed window with upper and lower apertures.

According to a fifth aspect there is provided a method of manufacturing a sensor package comprising: providing a radiation source and a radiation detector on a substrate; mounting or affixing a cover member on/to the substrate over the source and detector; wherein said cover member comprises: an opaque housing; a first transparent portion provided over the source; a second transparent portion provided over the detector; and a transparent insert within the housing and at one or more of said transparent portions.

### BRIEF DESCRIPTION OF THE DRAWINGS

The invention will now be described, by way of example only, with reference to the accompanying drawings in which:

FIG. 1 shows a plan view schematic layout of selected component parts of an example proximity sensor;

FIG. 2 shows a cover member according to an embodiment of the disclosure;

FIG. 3 shows further aspects of the cover member of FIG. 2;

FIG. 4 shows the cover member of FIGS. 2 and 3 assembled together with a proximity sensor of the type shown in FIG. 1;

FIG. 5 shows a side view of the package shown in FIG. 4; and

FIG. 6 shows a perspective view of an embodiment with air vents.

### DETAILED DESCRIPTION OF THE DRAWINGS

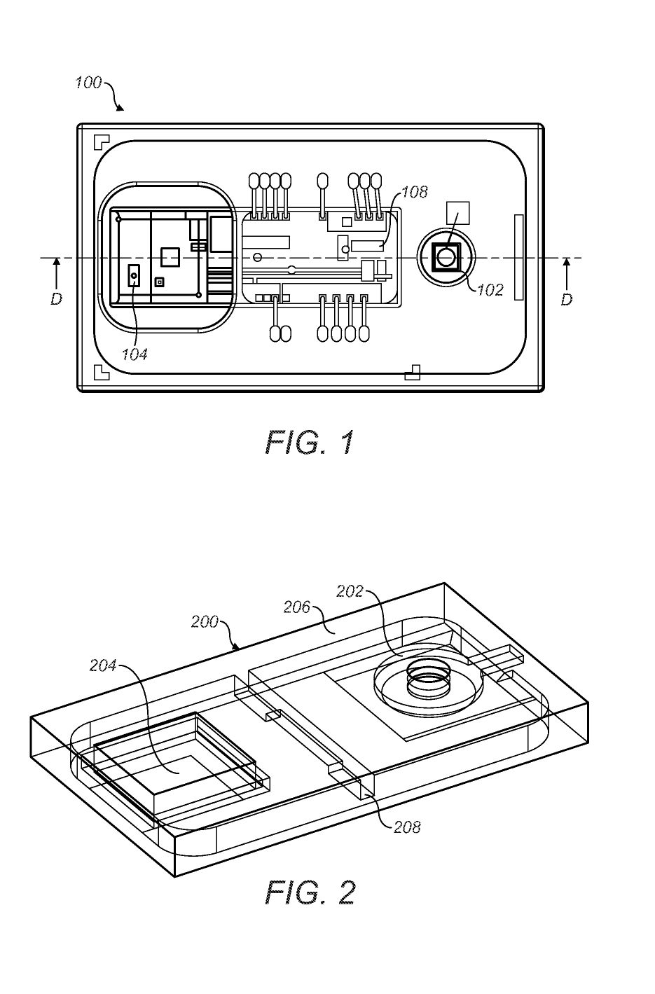

An example of a proximity sensor 100 is shown in FIG. 1, comprising radiation source 102 and radiation detector 104.

The radiation source 102 emits radiation which is reflected from an object and picked up by detector 104. The detector 100 may also be provided with other circuitry provided as part of the detector 104 or associated therewith, which analyzes the output from the detector for a proximity sensing calculation.

In some examples, the proximity sensing may for example be carried out based on a time of flight algorithm or a phase extraction algorithm. These methods yield a quantitative measurement of the distance of an object from the sensor package.

The direct time of flight (TOF) method may for example use a narrow pulsed laser as the radiation source, with a time-digital converter (TDC) being provided for measuring the difference in time between transmission and first photon reception. Commonly, a ‘reverse mode’ is employed, where the TDC measures the time from first photon reception to next pulse transmission. This scheme minimizes system activity to only the occasions where a photon is detected, and is therefore well matched to tightly controlled, low photon flux levels.

The phase extraction method measures the phase of the radiation incident on the detector 104. The phase shift between the radiation waveforms transmitted by the radiation source 102 and received at the detector 104 is indicative of the distance travelled by the radiation.

The example proximity sensor 100 shown in FIG. 1 comprises a vertical cavity surface emitting laser (VCSEL) 102 and a single photon avalanche detector (SPAD) 104. The VCSEL 102 may emit radiation in infrared or near infrared wavelengths. A reference detector 108 is also provided, close to the VCSEL 102. The reference detector 108 is arranged such that it does not receive light emitted by the main beam of the VCSEL 102. The purpose of the reference detector 108 is to act as a reference array which can, in effect, be used as a calibration for the main detector 104. It is possible that some radiation is emitted from the VCSEL 102 and propagates within a package of the proximity sensor 100 towards the reference array 108. By having a reference array 108, the main detector 104 can identify and therefore ignore spurious signals generated by propagation of radiation within the housing of the sensor package 100. It also serves as a way of determining the exact time of a pulse of emission radiated by the radiator 102. The proximity sensor 100 may also be provided with an ambient light sensor array. This may be provided close to the main detector 104. The ambient light sensor array is a relatively smaller array (comprising one or a small number of pixels) that is designed to detect levels of ambient light to wake up or calibrate the operation of the sensor 100.

It is also possible for a proximity sensor to be provided with different component parts. For example, the detector 104 can comprise a digital image sensor comprising an array of pixels which may, for example, comprise a charge coupled device (CCD) array or an array of pixels manufactured according to complimentary metal oxide semiconductor (CMOS) techniques. Furthermore, the radiation source 102 may emit radiation in other wavelength bands other than infrared or near infrared, and may also comprise a different type of emitter such as a light emitting diode (LED).

Proximity sensors such as the example shown in FIG. 1 are typically assembled in a package, which can in turn be incorporated in a host device, such as a mobile telephone or other electronic device, automobile or manufacturing equipment for example. The package may alternatively be formed at least in part integrally with a body or housing of the host device.

The components shown in FIG. 1 are formed on a substrate, which may be formed from a semiconductor material such as silicon for example. A proximity sensor package will normally comprise a cover member, which may be provided over the components shown in FIG. 1 and may attach (directly or indirectly) to the substrate. The package may also comprise optical components for performing optical functions including collimation of light emitted from the radiation source 102, or focusing of light onto the detector 104. The optical components may comprise a lens or series of lenses, or other optical elements providing the necessary optical functions, and may be provided as part of the cover member, on top of the cover member, or below the cover member.

FIG. 2 shows a cover member 200 according to an embodiment of the disclosure, which is suitable for assembly together with a proximity sensor 100 of the type shown in FIG. 1. The cover member 200 is provided with a first transparent portion 202 and a second transparent portion 204. The transparency of the first and second transparent portions 202, 204 is defined as permitting the transmission of radiation having a wavelength that matches the dominant wavelength of the radiation source 102. The transparent portions 202, 204 may comprise material, such as glass, so long as transparency in the relevant wavelength is ensured. The materials used may block the transmission of radiation that has other wavelengths such as some or all wavelengths from outside of a range either side of the dominant wavelength of the radiation emitted from the radiation source 102.

In the embodiment illustrated in FIG. 2, the first transparent portion comprises a glass window 202, which is transparent to infrared radiation. The glass window 202 is overmolded into the housing 206 of the cover member 200. The cover member 200 may be created by molding a round window on a sprue (for example a tree sprue) and then overmolding the housing 206 around the sprue to create an internally enclosed window with apertures top and bottom.

The window 202 is provided within the housing 206, in the sense of being supported by the housing and held securely therein without any further affixing mechanism being required for any orientation of the housing. Example formations that provide a window within the housing include the provision of a window having side surfaces entirely bounded by the housing; or the provision of a window having a perimeter portion bounded at least partially at both an upper and lower surface by the housing.

The term “window” used herein is used to refer to a flat planar object which can be of any chosen shape. The transparent insert may alternatively comprise other shapes as an alternative to a planar object, for example, an object having a substantially planar form but in addition being provided with deformations or protuberances (which may function as optical elements for various purposes); or having an entirely different shape altogether. In general, one or both of the transparent portions may be provided with a “transparent insert”. The transparent insert may provide an optical function. The optical function may be a focusing function, provided for example by a lens or other optical element, or a collimation function, provided by a collimating lens or other optical element. The term “insert” means a solid object; or a liquid constrained by a suitable container (an example being a liquid lens).

The housing 206 of the cover member may be formed from a material that is opaque to radiation emitted from the radiation source 102. For example, it may block the transmission of infrared and/or near infrared radiation. The housing 206 in a preferred implementation may also be opaque to all radiation in and/or around the visible spectrum, for example being formed of optically opaque thermoplastic molding material. In addition, the housing 206 may be formed from a material that is suitable for laser marking (engraving) to be applied. One example of a material that meets all these requirements (opacity and suitability for laser marking) is LCP 6130.

The cover member is also provided with a protrusion 208 formed between the first and second transparent portions 202, 204. The protrusion 208 extends from an underside surface of the housing 206 and functions to prevent or at least partially impede the transmission of radiation within the package and between a first portion of the package (containing the first transparent portion 202) and a second portion of the package (containing the second transparent portion 204). The protrusion in the illustrated embodiment extends across substantially the entire width of the housing 206, but it may in alternative embodiments be provided only partially along the width of the housing.

The second transparent portion 204 may be provided by forming an aperture in the housing 206.

The cover member 200 may also comprise an aperture formed through a top surface of the housing 206 which functions as an air vent. This helps regulate temperature of the device that is housed in the package, and is illustrated in FIG. 6.

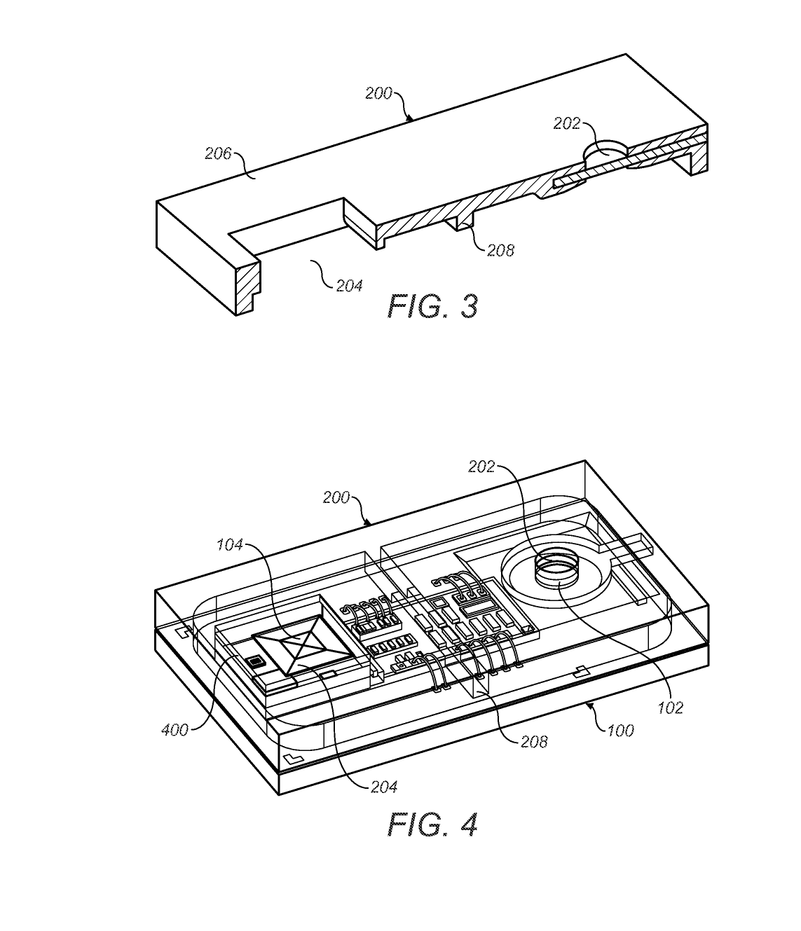

FIG. 3 shows a cut-away side perspective view of the cover member 200. The window can be seen as being integrally formed within the housing 206. A transparent portion 202 is provided by a cutout portion, providing in this example a circular portion that is provided over the window.

FIG. 4 shows the cover member 200 of FIGS. 2 and 3 assembled together with a proximity sensor 100 of the type shown in FIG. 1. As can be appreciated from this figure, the first transparent aperture 202 is formed in the cover member 200 at a position to overlay the radiation source 102 and the second transparent cover member 204 is formed in the cover member 200 at a position to overlay the detector 104.

The package can be fabricated by depositing an optically transparent glue over the VCSEL 102 and the reference detector 108, and then placing the plastic bridge 208 over this and then curing the glue. In conjunction with this a glass tile 400 may be placed over the detector 104. The part can then be processed by a film overmolding machine to encapsulate the components with black, light blocking material which blocks or at least partially impedes any direct light paths between the VCSEL illumination source 102 and the detector 104.

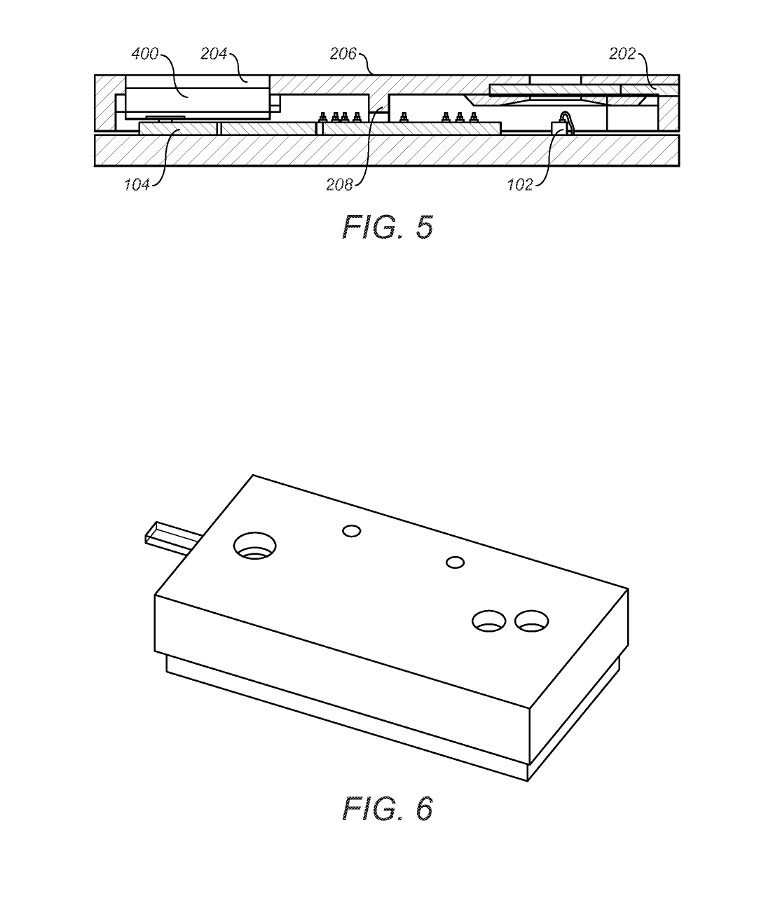

FIG. 5 shows a side view of the package shown in FIG. 4. Like parts are illustrated with like reference numerals. It can be seen here that the transparent portions 202, 204 comprise optical windows that are recessed with respect to the top surface of the cover member 200. This is a benefit as each of the window surfaces can add scatter to the system optical noise. Having the window surfaces recessed will assist greatly in reducing the system noise performance. Because imaging optics are not required, the design has a good tolerance to dimensional variations in the component parts of the package.

The protrusion 208 also helps optically isolate the detector 104 from the source 102, and also allows for a reference sample of the emitted light to be incident on a reference array.

The methods and novel products disclosed herein are easier to manufacture and cheaper to assemble than existing solutions. The product can be easily adapted to different requirements and different products.

The formation of a transparent plate having a perimeter portion bounded at both its upper and lower surfaces by the housing provides various technical effects. Firstly, the insert is generally more securely integrated with the body of the housing. Also, the bounding of a perimeter portion means that a flat plate can be used (as an optical element or filter for example), and can be securely held in a horizontal orientation without being tilted during the molding process. Also, in cases where a lensing or collimation function is provided as part of the transparent portion (the lens is formed as a protuberance from the plate), the perimeter portion provides some “play” that helps ensure accurate alignment of the lens. The structure of a sensor package described herein also lends itself more readily to the manufacturing environment of the manufacture of proximity sensors for use in mobile devices and for radiation sensing.

Various improvements and modifications can be made to the above without departing from the scope of the disclosure.

What is claimed is:

1. A sensor package, comprising:
a radiation source and radiation detector provided on a substrate;
a cover member mounted on or affixed to the substrate over the source and detector, said cover member comprising:
an opaque housing;
a first transparent portion provided over the source;
a second transparent portion provided over the detector; and
a transparent plate positioned at one of said transparent portions, the transparent plate having a perimeter portion bounded at both its upper and lower surfaces by the housing.

2. The sensor package of claim 1, wherein the transparent plate comprises a window.

3. The sensor package of claim 1, wherein the transparent plate comprises a surface shaped to provide a focusing function.

4. The sensor package of claim 1, wherein the transparent plate comprises a surface shaped to provide a collimation function.

5. The sensor package of claim 1, wherein the transparent plate spans the transparent portion.

6. The sensor package of claim 1, wherein both first and second transparent portions comprise a transparent plate within the housing.

7. The sensor package of claim 1, wherein one of said first and second transparent portions comprises a transparent plate within the housing and the other of said first and second transparent portions comprises an aperture in the housing.

8. The sensor package of claim 1, wherein the first transparent portion comprises a transparent plate within housing; and the second transparent portion comprises an aperture in the housing.

9. The sensor package claim 1, wherein the housing also comprises a protrusion formed between the first and second transparent portions.

10. The sensor package of claim 9, wherein the protrusion provides a transverse barrier across a central portion of the width of the package.

11. The sensor package of claim 9, wherein the protrusion provides a transverse barrier across the entire width of the package.

12. The sensor package of claim 9, wherein the protrusion extends downwards and contacts the substrate or other underlying components.

13. The sensor package of claim 1, wherein at least one of the first and second transparent portions are flush with respect to an upper surface of the housing.

14. The sensor package of claim 1, wherein at least one of the first and second transparent portions are recessed with respect to an upper surface of the housing.

15. The sensor package of claim 1, wherein the housing is formed from optically opaque thermoplastic molding material.

16. The sensor package of claim 1, wherein the housing comprises an aperture which functions as an air vent for the packaged sensor.

17. The sensor package of claim 1, wherein the source comprises a VCSEL.

18. The sensor package of claim 1, wherein the detector comprises a SPAD.

19. The sensor package of claim 1, wherein the package comprises a reference array.

20. The sensor package of claim 1, wherein the package comprises an ambient light sensor.

21. A cover member, comprising:
an opaque housing;
a first transparent portion;
a second transparent portion; and
a transparent plate having a perimeter portion bounded at both its upper and lower surfaces by the housing.

22. A method of manufacturing a sensor package for a device including a radiation source and a radiation detector mounted on a substrate, comprising:
forming a cover member with an opaque housing, a first transparent portion to be provided over the source, a second transparent portion to be provided over the detector;
forming a transparent plate at one or more of said transparent portions, the transparent plate having a perimeter portion bounded at both its upper and lower surfaces by the housing; and
mounting the cover member to the substrate.

23. The method of claim 22, wherein mounting comprises depositing a transparent glue and placing a portion of the package over the glue.

24. The method of claim 23, wherein the placed portion comprises an opaque protrusion that is formed between the first and second transparent portions.

25. A method of forming a cover member, comprising:
forming an opaque housing with a first transparent portion to be provided over the source and a second transparent portion to be provided over the detector; and
forming a transparent plate at one or more of said transparent portions, the transparent plate having a perimeter portion bounded at both its upper and lower surfaces by the housing.

26. The method of claim 25, comprising a twin-shot injection overmolding process; wherein the transparent plate is formed and then the cover member is overmolded onto the window.

27. The method of claim 26, wherein the transparent plate is formed by molding round a tree sprue and the housing is overmolded around the tree sprue to create an internally enclosed window with upper and lower apertures.

28. A method of manufacturing a sensor package including a radiation source and a radiation detector mounted on a substrate, comprising:
mounting a cover member to the substrate over the source and detector;
wherein said cover member comprises:
an opaque housing;
a first transparent portion provided over the source;
a second transparent portion provided over the detector; and
a transparent plate at one or more of said transparent portions, the transparent plate having a perimeter portion bounded at both its upper and lower surfaces by the housing.
